(19) United States
(12) Patent Application Publication
(10) Pub. No.: US 2026/0013372 A1
(43) Pub. Date: Jan. 8, 2026

(54) DISPLAY DEVICE

(71) Applicant: LG Display Co., Ltd., Seoul (KR)

(72) Inventors: Hyoyoung JUN, Paju-si (KR); Minsu KIM, Paju-si (KR); Youngtaek HONG, Paju-si (KR)

(73) Assignee: LG Display Co., Ltd., Seoul (KR)

(21) Appl. No.: 19/236,801

(22) Filed: Jun. 12, 2025

(30) Foreign Application Priority Data
Jul. 8, 2024 (KR) 10-2024-0089425

(51) Int. Cl. H10K 59/80; H10K 59/122; H10K 59/40

(52) U.S. Cl. CPC H10K 59/873; H10K 59/122; H10K 59/40

(57) ABSTRACT

There is disclosed a display device including a substrate comprising a display area including a pixel, and a non-display area disposed adjacent to the display area; at least one panel inorganic layer on the substrate; a clad part disposed on the at least one panel inorganic layer in the non-display area and configured to cover an end of the at least one panel inorganic layer; and a touch part disposed on the clad part and comprising at least one touch inorganic layer and a touch electrode on the at least one touch inorganic layer, and the at least one panel inorganic layer or the at least one touch inorganic layer may include a stop hole overlapping the clad part.

This application claims priority to and the benefit of Korean Patent Application No. 10-2024-0089425, filed on Jul. 8, 2024, the disclosure of which is incorporated herein by reference in its entirety.

### BACKGROUND

### Technical Field

Embodiments of the present disclosure relate to a display device.

### Background of the Disclosure

As the information society develops, various demands for display devices that display images are increasing, and various types of display devices, such as liquid crystal displays and organic light emitting diode displays, are being used.

A display device may include a plurality of pixels and a plurality of switching elements configured to drive and control the pixels.

### SUMMARY

Accordingly, one object of embodiments of the present disclosure is to solve the above-noted disadvantages of the prior art, and embodiments of the present disclosure may provide a display device having a narrow bezel.

Another object of the embodiments is to provide a display device with secured rigidity of trim line (i.e., edge).

A further object of the embodiments is to provide a display device in which an attachment metal is disposed on a stop hole formed on a clad part and lifting between inorganic films or peeling between films can be improved.

A still further object of the embodiments is to provide a display device that may relieve the stress of films and is robust against film lifting by strengthening the adhesion between the films.

A still further object of the embodiments is to provide a display device that may be robust against crack propagation.

Aspects according to the present disclosure are not limited to the above ones, and other aspects and advantages that are not mentioned above can be clearly understood from the following description and can be more clearly understood from the example embodiments set forth herein.

To achieve these objects and other advantages of the present disclosure, a display device according to an example embodiment of the present disclosure may include a substrate comprising a display area including a pixel, and a non-display area disposed adjacent to the display area; at least one panel inorganic layer on the substrate; a clad part disposed on the at least one panel inorganic layer in the non-display area and configured to cover an end of the at least one panel inorganic layer; and a touch part disposed on the clad part and comprising at least one touch inorganic layer and a touch electrode on the at least one touch inorganic layer, and the at least one panel inorganic layer or the at least one touch inorganic layer may include a stop hole overlapping the clad part.

In another aspect, a display device according to another example embodiment of the present disclosure may include a substrate comprising a display area including a pixel, and a non-display area disposed adjacent to the display area; at least one panel inorganic layer on the substrate; a clad part disposed on the at least one panel inorganic layer in the non-display area and configured to cover an end of the at least one panel inorganic layer; a dam disposed between the clad part and the display area; and a touch part disposed on the clad part and the dam, and comprising at least one touch inorganic layer and a touch electrode on the at least one touch inorganic layer. The at least one touch inorganic layer may include a stop hole, and the stop hole may be disposed between the clad part and the dam.

Specific descriptions of various example embodiments are provided in detailed description and the accompanying drawings.

According to example embodiments of the present disclosure, the display device may include the clad part arranged near the left, right, or upper end of the display panel, and at least one panel inorganic layer may include the first stop hole extending through the thickness direction, or at least one touch inorganic layer may include the second stop hole extending through the thickness direction. The clad part may be in contact with the substrate through the first stop hole, and the first touch organic layer may be in contact with the clad part through the second stop hole. The clad part, the substrate, and the first touch organic layer may each include the organic material. Therefore, the display device according to the embodiments can improve film lifting by strengthening adhesion between films on the cladding portion.

Furthermore, In the display device according to example embodiments, the first stop hole and the second stop hole can be formed in the clad part located at the outermost side of the display panel. As a result, no separate stop hole needs to be formed on the inner surface of the clad part (or the non-display area between the clad part and the display area), thereby achieving a narrow bezel.

Still further, the display device according to example embodiments of the present disclosure can block a crack from occurring at the end of the display panel caused by an external force at the outermost end by forming the first stop hole and the second stop hole in the clad part located at the outermost end of the display panel.

Still further, the display device according to example embodiments can improve moisture penetration into the display area through the crack by blocking the crack at the end of the display panel through the first and second stop holes at the outermost end, thereby improving the service life.

Still further, the display device according to example embodiments may further include the attachment metal disposed within the first stop hole or the second stop hole. The attachment metal may improve peeling or lifting between the inorganic layers by directly contacting the lateral surfaces of the inorganic layers exposed by the first stop hole or the second stop hole.

In addition to the above-described effects, specific effects of the present disclosure will be described together with the following detailed description for implementing the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings:

FIG. 1 is a plane view showing a display device according to an example embodiment;

FIG. 2 is a cross-sectional view showing a state where a display shown in FIG. 1 is bent;

FIG. 3 is a plane view showing a state where a display shown in FIG. 1 is bent;

FIG. 4 is a cross-sectional view cut along A-A′ in FIG. 3;

FIG. 5 is a cross-sectional view cut along B-B′ in FIG. 3;

FIG. 6 is an enlarged cross-sectional view of area Q1 shown in FIG. 5;

FIG. 7 is a cross-sectional view cut along C-C′ in FIG. 3;

FIG. 8 is an enlarged cross-sectional view of area Q2 shown in FIG. 7;

FIG. 9 is a cross-sectional view of a display device according to another example embodiment;

FIG. 10 is a cross-sectional view of a display device according to a further example embodiment;

FIG. 11 is a cross-sectional view of a display device according to a comparative example;

FIG. 12 is a cross-sectional view of a display device according to a further example embodiment;

FIG. 13 is a cross-sectional view of a display device according to a still further example embodiment; and

FIG. 14 is a cross-sectional view of a display device according to a still further example embodiment.

### DETAILED DESCRIPTION

Reference will now be made in detail to various embodiments of the present disclosure, examples of which are illustrated in the accompanying drawings.

Below, various example embodiments according to the present disclosure are specifically described with reference to the accompanying drawings. In the drawings, identical reference numerals can denote identical or similar components.

It should be understood that where an element is referred to as being “connected with,” “on,” or “coupled to” another element, the element can be directly connected with the other element or intervening elements may also be present. In contrast, where an element is referred to as being “directly connected with” another element, there are no intervening elements present.

“And/or” includes any combination of one or more of the associated elements that can be defined.

It should be understood that, although the terms first, second, etc. may be used herein to describe various elements, these elements should not be limited by these terms. These terms are generally only used to refer to one element separately from another. It should be understood that the terms “first” and “second” are used herein to describe various components, but these components should not be limited by these terms. The above terms are used only to refer to one component separately from another. For example, a first component may be referred to as a second component, and vice versa, without departing from the scope of the disclosure. The singular expressions include plural expressions, and vice versa, unless the context clearly dictates otherwise.

Terminologies such as “under,” “below,” “on,” “above,” etc., are used to describe location relationship between the elements shown in the drawings. Such terminologies are relative concepts and described with respect to directions shown in the accompanying drawings. In contrast, where an element is referred to as being “directly connected with” another element, there are no intervening elements present. Unless a more limiting term like “immediately” or “directly” is used when describing location relationship, for example, “on,” “above,” “under,” “next,” etc., one or more other elements may be also present.

Throughout the disclosure, each component can be provided as a single one or a plurality of ones, unless explicitly stated to the contrary. Terms such as “include” or “has” are used herein and should be understood that they are intended to indicate an existence of several components, functions or steps, disclosed in the specification, and it should also be understood that greater or fewer components, functions, or steps may likewise be utilized. A singular representation may include a plural representation unless it represents a definitely different meaning from the context. In understanding the components, it should be understood as including the error range even if there is no separate explicit description.

Features of various embodiments may be partially or entirely combined with each other, and various connections and driving are possible. Also, embodiments may be implemented independently or implemented in a related relationship.

Hereinafter, a display device according to various example embodiments will be described with reference to the accompanying drawings.

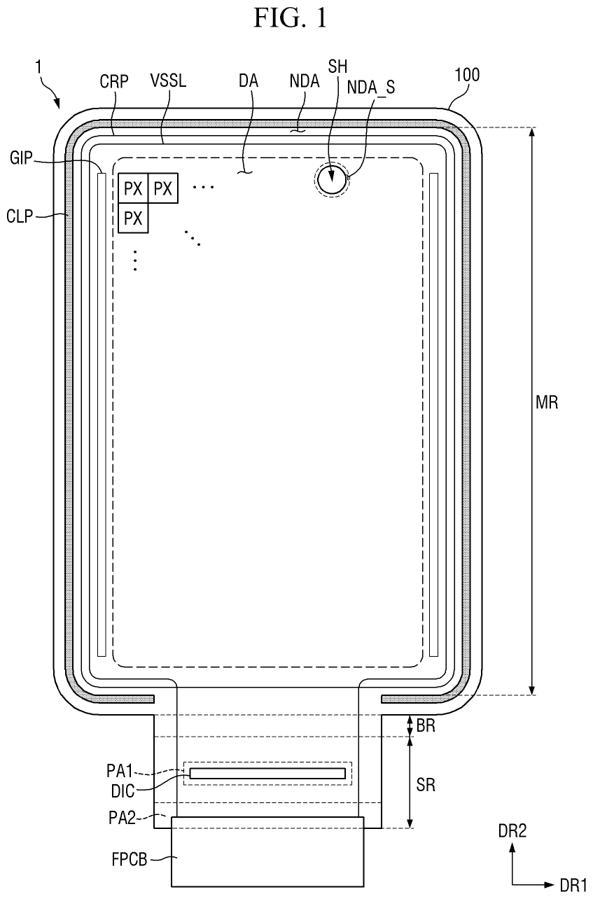

FIG. 1 is a plane view showing a display device according to an example embodiment.

As shown in FIG. 1, a display device 1 according to one embodiment may include a display panel 100. The display panel 100 may include a display area DA including a plurality of pixels PX; and a non-display area NDA adjacent to the display area DA. The display area DA may have a rectangular shape. However, the embodiments are not limited thereto and the planar shape of the display area DA may be a square, a circle, an ellipse, or other polygonal shape. For example, the display area (DA) may be a rectangular shape with rounded corners, but is not limited thereto, and may also be a rectangular shape with sharp corners.

The first direction DR1 and the second direction DR2 are different directions and represent directions that intersect each other, for example, directions that intersect perpendicularly on a plane. In FIG. 1, the first direction DR1 may be generally the same as the extension direction of the short sides of the display panel 100, and the second direction DR2 may be the same as the extension direction of the long sides of the display panel 100. However, it should be understood that the directions mentioned in the embodiment refer to relative directions, and the embodiments are not limited to the mentioned directions.

The display area DA may include short sides extending along the first direction DR1 and long sides extending along the second direction DR2. A non-display area NDA may surround the display area DA. The non-display area NDA can be arranged on one side of the display area DA in the first direction DR1, the other side of the first direction DR1, one side of the second direction DR2, and the other side of the second direction DR2.

The display panel 100 may include a sensor non-display area NDA_S, and a sensor hole SH surrounded by the sensor non-display area NDA_S. the sensor hole SH may be surrounded by the display area DA on a plane. One sensor hole SH may be provided as shown in FIG. 1 but the embodiments are not limited thereto. For example, two sensor holes SH may be provided, and each of the two sensor holes SH may include a sensor hole in which an infrared sensor is arranged and a sensor hole in which a camera sensor is arranged, but the embodiments are not limited thereto. The sensor non-display area NDA_S may be disposed between the sensor hole SH and the display area DA. The sensor non-display area NDA_S may completely surround the sensor hole SH. No pixels PX may be disposed in the sensor non-display area NDA_S. In some embodiments, the display panel 100 may include an optical area, without the sensor hole SH. One or more optical areas may be arranged to overlap one or more optical electronic devices, such as an imaging device such as a camera (or image sensor), a detection sensor such as a proximity sensor, and a light sensor.

One or more optical regions may have a light-transmitting structure formed therein to have a transmittance equal to or greater than a certain level for the operation of the optical electronic device. In other words, the number of pixels per unit area in one or more optical areas may be smaller than the number of pixels per unit area in the general area excluding the optical area in the display area DA. In other words, the resolution of one or more optical areas may be lower than the resolution of the general area in the display area (DA).

The light transmitting structure in one or more optical areas can be formed by patterning the cathode electrode in an area where no pixels are arranged. At this time, the cathode electrode to be patterned can be removed using a laser, or the cathode electrode can be selectively formed and patterned by using a material such as a cathode deposition prevention layer.

In addition, the light-transmitting structure in one or more optical areas may be configured by forming the light-emitting element and the pixel circuit separately in the pixel. In other words, the light-emitting element of the pixel is positioned on the optical area, and a plurality of transistors constituting the pixel circuit are arranged on the periphery of the optical region, so that the light-emitting element and the pixel circuit can be electrically connected through the transparent metal layer.

A gate driver GIP may be placed on each of the non-display area NDA located on one side of the first direction DR1 of the display area (DA) and the other side of the first direction DR1. A low voltage line VSSL may be arranged outside the gate driver GIP in the non-display area NDA. For example, as shown in FIG. 1, the low voltage line VSSL may extend from the printed circuit board FPCB, pass through the sub-region SR and the bending region BR, be positioned outside the gate driver GIP in the non-display area ND, and be arranged to surround the display area DA.

The non-display area NDA located on the other side of the second direction DR2 of the display area DA can extend further in the other direction of the second direction DR2 from the center of the other side of the second direction DR2 of the display area DA. In the central portion of the other side of the second direction DR2 of the display area DA, the width in the first direction DR1 of the non-display area NDA extending further in the other side of the second direction DR2 may be smaller than the width in the first direction DR1 of the non-display area NDA adjacent to the other side of the second direction DR2 of the display area DA.

The display device 1 may include a main-region MR, a sub-region SR, and a bending region BR between the main-region MR and the sub-region SR and display area DA and the non-display area NDA surrounding four sides of the display area DA, which are described above, may form the main-region MR. In the central portion of the other side of the second direction DR of the display area DA, a portion extending further in the other direction of the second direction DR2 can form a bending region BR and a sub-region SR. The bending region BR may be disposed between the sub-region SR and the main-region MR. the sub-region SR may include a first pad area PA1 and a second pad area PA2 disposed at the other end of the second direction DR2 of the sub-region SR. the display device 1 may further include a data driver DIC and a printed circuit board FPCB. The data driver DIC may be disposed on the first pad area PA1 and the printed circuit board FPCB may be attached to the second path area PA2. On the first pad area PA1 and the second pad area PA2, multiple pads connected to the data driver DIC and the printed circuit board FPCB may be arranged. For example, the data driver DIC may be formed as, for example, a driver chip IC, but the embodiments are not limited thereto. In one embodiment, the data driver DIC is arranged in the form of a chip on plastic directly mounted on the display panel 100, but the embodiments are not limited thereto and may be arranged in the form of a chip on glass or a chip on film.

The display panel 100 according to one embodiment may further include a clad part CLP. The clad part CLP may be disposed on the main-region MR, and not on the bending region BR and the sub-region SR. the clad part CLP may be disposed in the non-display area NDA. The clad part CLP can be arranged in the non-display area NDA on one side of the first direction DR1 of the display area DA, the non-display area NDA on the other side of the first direction DR1, and the non-display area NDA on one side of the second direction DR2. The clad parts CLPs arranged in the non-display area NDA on one side of the first direction DR1 of the display area DA, the non-display area NDA on the other side of the first direction DR1, and the non-display area NDA on one side of the second direction DR2 may be formed integrally, but the embodiments of the present specification are not limited thereto. The clad part CLP may also be arranged to partially extend into the non-display area NDA on the other side of the second direction DR2 of the display area DA, but the embodiments of the present specification are not limited thereto. The clad parts CLPs arranged in the non-display area NDA on one side of the first direction DR1 of the display area DA, the non-display area NDA on the other side of the first direction DR1, and the non-display area NDA on one side of the second direction DR2 may be formed integrally, but the embodiments of the present specification are not limited thereto. The clad part CLP may also be arranged to partially extend into the non-display area NDA on the other side of the second direction DR2 of the display area DA, but the embodiments of the present specification are not limited thereto.

The display panel 100 according to one embodiment may further include a crack detecting pattern CRP arranged between the clad part CLP and the low voltage line VSSL. The crack detecting pattern CRP may be arranged to completely surround the display area DA, as shown in FIG. 1. For example, the crack detecting pattern CRP may be placed between the clad part CLP and the low voltage line VSSL. However, the embodiments of the present specification are not limited thereto, and the crack detecting pattern CRP may not be placed in some of the non-display area NDA on the other side of the second direction DR2 of the display area DA. In some embodiments, the crack detecting pattern may be formed as a circuit in a non-display area NDA on one side of the second direction DR2 of the display area DA. In this case, the crack detecting pattern may be composed of two wires, and the wire of one crack detecting pattern may be located on the left side (or the other side of the second direction DR2) and the wire of the other crack detecting pattern may be located on the right side (or one side of the second direction DR2).

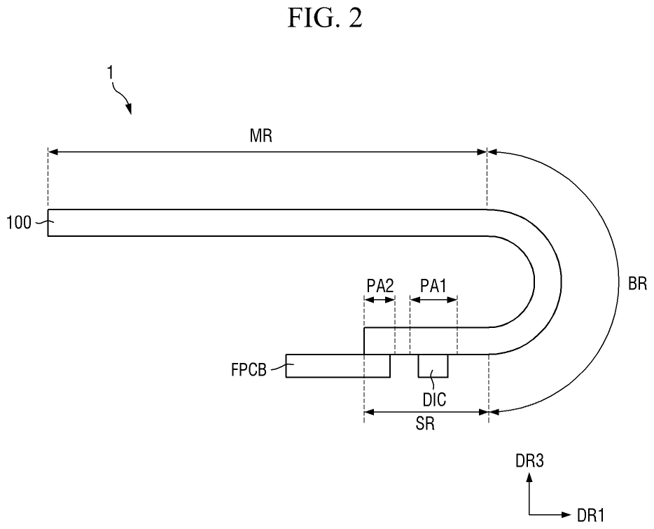

FIG. 2 is a cross-sectional view showing a state where a display shown in FIG. 1 is bent.

As shown in FIG. 2, the bending region BR of the display panel 100 of the display device 1 according to one embodiment may be bent in the thickness direction (or third direction). Due to this, the main-region MR and the sub-region SR can overlap in the thickness direction. The display panel 100 can be bent in such a way that the lower surface of the main-region MR and the upper surface of the sub-region SR face each other. The printed circuit board FPCB can be attached to an end of the sub-region SR.

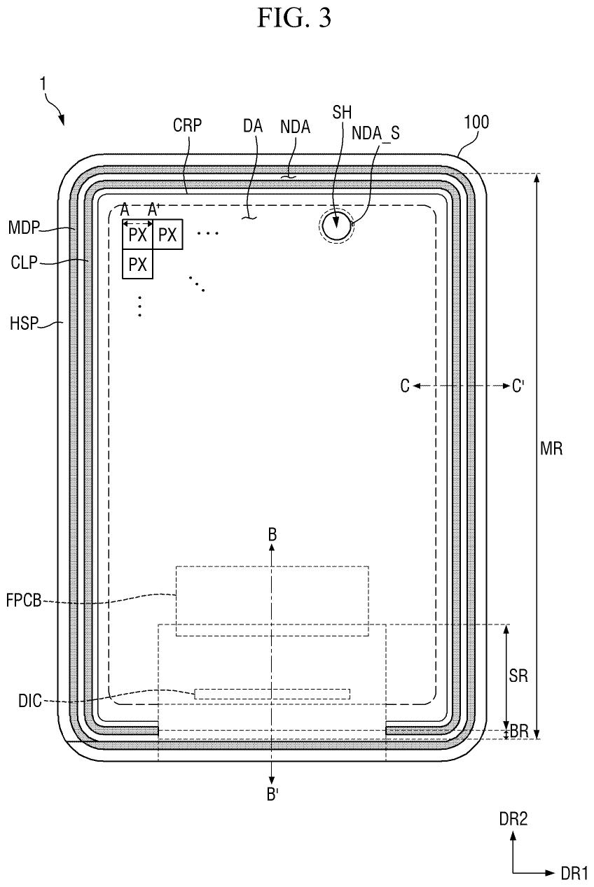

FIG. 3 is a plane view showing a state where a display shown in FIG. 1 is bent.

As shown in FIG. 3, the display device 1 may further include a mold MDP and a housing HSP.

The bending region BR of the display panel 100 is bent so that the sub-region SR may overlap the main-region MR. The printed circuit board FPCB and the data driver DIC each may overlap the main-region MR.

The mol A mold MDP may be placed on the outside of the display panel 100. The mold MDP may be placed along the edge of the bent display panel 100. The mold MDP can be in direct contact with the side of the bent display panel 100. The mold MDP can include an organic material. As shown in FIG. 3, the mold MDP can include an organic material that repeats shrinkage and expansion based on heat.

A housing HSP may be placed on the outside of the display panel 100 and the mold MDP. The housing HSP may be placed along the edge of the mold MDP.

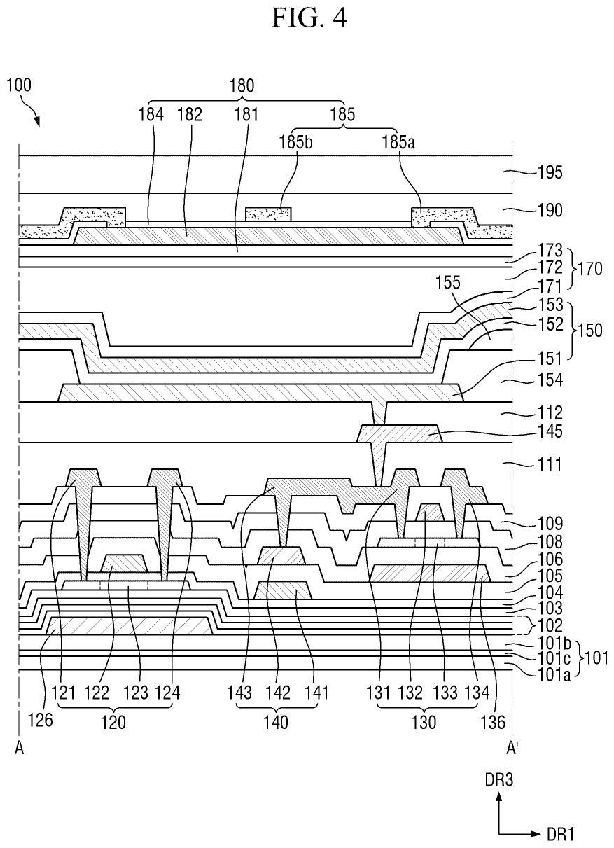

FIG. 4 is a cross-sectional view cut along A-A′ in FIG. 3.

As shown in FIG. 4, the display panel 100 may include a substrate 101, a first thin film transistor 120, a second thin film transistor 130, a light emitting part 150, an encapsulating part 170, a touch part 180, a touch organic layer 190 and 195. The display panel 100 may include at least one panel inorganic layer and at least one touch inorganic layer between the substrate 101 and the light-emitting part 150. The at least one panel inorganic layer may include at least one of the buffer layer 102, the first insulating layer 103, the second insulating layer 104, the third insulating layer 105, the fourth insulating layer 106, the fifth insulating layer 108, and the sixth insulating layer 109 described above, and the at least one touch inorganic layer may include at least one of the touch buffer layer 181 and the insulating layer 184.

The substrate 101 may include one or more plastic materials. For example, the substrate 101 may be a multi-substrate including a plurality of plastic materials such as polyimide. For example, the substrate 101 may include a first substrate portion 101a, a second substrate portion 101b, each including a plastic material, and a third substrate portion 101c including an inorganic material between the first substrate portion 101a and the second substrate portion 101b, but the embodiments are not limited thereto.

A first 1ight-blocking layer 126 may be placed on the substrate 101. The first 1ight-blocking layer 126 may prevent light from being transmitted to the first semiconductor layer 123 of the first thin film transistor 120. For example, the first semiconductor layer 123 may be arranged to overlap the first 1ight-blocking layer 126. The first 1ight-blocking layer 126 may be a single layer or multiple layers made of one of molybdenum (Mo), aluminum (Al), chromium (Cr), nickel (Ni), neodymium (Nd), and copper (Cu) or an alloy thereof, but the embodiments are not limited thereto.

The buffer layer 102 may be placed on the first 1ight blocking layer 126. The buffer layer 102 may minimize or delay the diffusion of moisture or oxygen penetrating the substrate 101. The buffer layer 102 may be formed by alternately stacking silicon nitride (SiNx) and silicon oxide (SiOx) at least once, but the embodiments are not limited thereto.

The first insulating layer 103 may be arranged on the buffer layer 102. The first insulating layer 103 may prevent a short between the configuration of the first thin film transistor 120 and the first 1ight-blocking layer 126. The first insulating layer 103 may be made of the same material as the buffer layer 102, but the embodiments are not limited thereto. For example, the first insulating layer 103 may be made of an inorganic material such as silicon nitride (SiNx) or silicon oxide (SiOx), but the embodiments are not limited thereto.

The first thin film transistor 120 may be placed on the first insulating layer 103. The first thin film transistor 120 may include a first source electrode 121, a first gate electrode 122, a first semiconductor layer 123, and a first drain electrode 124.

The first semiconductor layer 123 may be disposed on the first insulating layer 103. The first semiconductor layer 123 may include a metal oxide semiconductor such as IGZO (Indium-Gallium-Zinc Oxide), a silicon-based semiconductor material such as amorphous silicon or polycrystalline silicon, but the embodiments are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be low and reliability can be excellent. Accordingly, the driving transistor can be composed of a polycrystalline semiconductor layer.

The second insulating layer 104 may be arranged on the first semiconductor layer 123. The second insulating layer 104 may be made of the same material as the first insulating layer 103, and may prevent a short circuit between the first semiconductor layer 123 and other components of the first thin film transistor 120.

A first gate electrode 122 may be arranged on the second insulating layer 104. The first gate electrode 122 may be arranged on the second insulating layer 104 so as to overlap with the channel region of the first semiconductor layer 123. The first gate electrode 122 may be composed of a single layer or multiple layers including molybdenum (Mo), copper (Cu), titanium (Ti), aluminum (Al), chromium (Cr), gold (Au), nickel (Ni), neodymium (Nd), or compounds thereof, but the embodiments are not limited thereto. The first gate electrode 122 may be arranged together with a gate line.

A third insulating layer 105 may be placed on the first gate electrode 122. The third insulating layer 105 may be made of the same material as the first insulating layer 103 or the second insulating layer 104, but the embodiments of the present specification are not limited thereto.

On the third insulating layer 105 may be disposed the first source electrode 121 and the first drain electrode.

The first source electrode 121 and the first drain electrode 124 can be electrically connected to the first semiconductor layer 123 through a contact hole. The first source electrode 121 and the first drain electrode 124 can be formed of a metal material. For example, the first source electrode 121 and the first drain electrode 124 may be formed of a single layer or multiple layers made of one or an alloy of molybdenum (Mo), aluminum (Al), chromium (Cr), gold (Au), titanium (Ti), nickel (Ni), neodymium (Nd), and copper (Cu), but the embodiments are not limited thereto.

The first source electrode 121 and the first drain electrode 124 may be arranged together with the data line. For example, the data line may be formed in the same layer with the same material as the first source electrode 121 and the first drain electrode 124, but the embodiments are not limited thereto.

A storage electrode 140 may be placed apart from the first thin film transistor 120. The storage electrode 140 may include a first storage electrode 141, a second storage electrode 142, and a third storage electrode 143.

The first storage electrode 141 may be arranged in the same layer with the same material as the first gate electrode 122, but the embodiments are not limited thereto.

A second storage electrode 142 may be placed on the first storage electrode 141. The second storage electrode 142 may be placed on the third insulating layer 105, and a capacitance may be formed by using the third insulating layer 105 between the first storage electrode 141 and the second storage electrode 142 as a dielectric. The second storage electrode 142 may be made of the same material as the first storage electrode 141, but the embodiments are not limited thereto.

A second thin film transistor 130 may be placed spaced apart from the first thin film transistor 120 and the storage electrode 140. The second thin film transistor 130 may include a second source electrode 131, a second gate electrode 132, a second semiconductor layer 133, and a second drain electrode 134.

A second light-blocking layer 136 may be placed on the same layer as the second storage electrode 142.

The second light-blocking layer 136 can prevent light from reaching the second semiconductor layer 133 similarly to the first 1ight-blocking layer 126, thereby extending the life of the second thin film transistor 130. For example, the second semiconductor layer 133 can be arranged to overlap the second light-blocking layer 136.

A fourth insulating layer 106 may be placed on the second shading layer 136. The fourth insulating layer 106 may be the same material as the first insulating layer 103, the second insulating layer 104, or the third insulating layer 105, but the embodiments are not limited thereto.

A second semiconductor layer 133 may be arranged on the fourth insulating layer 106. The second semiconductor layer 133 may include a source area, a drain area, and a channel area between the source area and the drain area.

The second semiconductor layer 133 may include a metal oxide semiconductor such as IGZO (Indium-Gallium-Zinc Oxide), a silicon-based semiconductor material such as amorphous silicon or polycrystalline silicon, but the embodiments are not limited thereto.

A fifth insulating layer 108 may be arranged on the second semiconductor layer 133. The fifth insulating layer 108 may be the same material as the first insulating layer 103, the second insulating layer 104, the third insulating layer 105, or the fourth insulating layer 106, but the embodiments are not limited thereto.

The second gate electrode 132 may be arranged on the fifth insulating layer 108.

The second gate electrode 132 may be made of the same material as the first gate electrode 122. For example, the second gate electrode 132 may be formed as a single layer or multiple layers including molybdenum (Mo), copper (Cu), titanium (Ti), aluminum (Al), chromium (Cr), gold (Au), nickel (Ni), neodymium (Nd), or compounds thereof, but the embodiments are not limited thereto.

A sixth insulating layer 109 may be arranged on the second gate electrode 132. The sixth insulating layer 109 may be the same material as the first insulating layer 103, the second insulating layer 104, the third insulating layer 105, the fourth insulating layer 106, or the fifth insulating layer 108, but the embodiments are not limited thereto.

The first source electrode 121, the first drain electrode 124, the third storage electrode 143, the second source electrode 131, and the second drain electrode 134 may be arranged on the sixth insulating layer 109.

The third storage electrode 143, the second source electrode 131, and the second drain electrode 134 may be made of the same material as the first source electrode 121 and the first drain electrode 124, and may be arranged in the same layer, but the embodiments are not limited thereto. For example, the third storage electrode 143, the second source electrode 131, and the second drain electrode 134 may be a single layer or multiple layers made of one of molybdenum (Mo), aluminum (Al), chromium (Cr), gold (Au), titanium (Ti), nickel (Ni), neodymium (Nd), and copper (Cu), or an alloy thereof, but the embodiments are not limited thereto. For example, the third storage electrode 143 and the second source electrode 131 may be directly connected, but the embodiments are not limited thereto.

The first thin film transistor 120 may be a driving transistor, and the second thin film transistor 130 may be a switching transistor, but the embodiments are not limited thereto.

A first protective layer 111 may be placed on the first source electrode 121 and the first drain electrode 124.

The first protective layer 111 can planarize the upper portion of the first thin film transistor 120 and protect the first thin film transistor 120. The first protective layer 111 can be made of an organic material. For example, the first protective layer 111 can be formed of an organic material including an acrylic resin, an epoxy resin, a phenolic resin, a polyamide resin, or a polyimide resin, but the embodiments are not limited thereto.

A second protective layer 112 may be placed on the first protective layer 111. The second protective layer 112 may be formed of the same material as the first protective layer 111, but the embodiments are not limited thereto.

A connecting electrode 145 may be placed between the first protective layer 111 and the second protective layer 112.

The connecting electrode 145 can electrically connect the first thin film transistor 120 and the light emitting part 150. The connecting electrode 145 can be made of the same material as the first source electrode 121 and the first drain electrode 124, but the embodiments are not limited thereto.

The connecting electrode 145 may be a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments are not limited thereto.

The light-emitting part 150 may be placed on the second protective layer 112. The light-emitting part 150 may include an anode electrode 151, an organic layer 152, and a cathode electrode 153.

The anode electrode 151 may be arranged on the second protective layer 112. The anode electrode 151 may be electrically connected to the first thin film transistor 120 through a contact hole formed in the second protective layer 112. The anode electrode 151 may be a reflective electrode that reflects light, but the embodiments of the present specification are not limited thereto. The anode electrode 151 may include a highly reflective metal material such as a laminated structure of aluminum (Al) and titanium (Ti) (Ti/Al/Ti), a laminated structure of aluminum (Al) and ITO (ITO/AI/ITO), or an APC alloy, and may be formed of a single layer or multiple layers, but the embodiments of the present specification are not limited thereto.

An organic layer 152 may be disposed on the anode electrode 151. The organic layer 152 may include one or more light-emitting structures (or light-emitting elements or elements) laminated in the order or reverse order of the hole transport layer and the electron transport layer on the anode electrode 151. For example, the hole transport layer may include a hole transport layer, a hole injection layer, an electron blocking layer, or a P-type charge generation layer, but the embodiments of the present specification are not limited thereto. For example, the electron transport layer may include an electron transport layer, an electron injection layer, a hole blocking layer, or an N-type charge generation layer, but the embodiments of the present specification are not limited thereto. The organic layer 152 may be an organic light-emitting layer, an inorganic light-emitting layer, a quantum dot light-emitting layer, a micro light-emitting diode, or a micro mini light-emitting diode, but the embodiments are not limited thereto. For example, the organic layer 152 of the display panel 100 according to one embodiment of the present specification may include an organic light-emitting layer. The organic layer 152 may include a red light-emitting layer, a green light-emitting layer, and a blue light-emitting layer. The organic layer 152 may further include a white light-emitting layer, but the embodiments are not limited thereto.

A cathode electrode 153 may be placed on the organic layer 152. The cathode electrode 153 may be a transparent electrode that transmits light, but the embodiments are not limited thereto. For example, the cathode electrode 153 may include a transparent conductive material such as ITO (Indium Tin Oxide) or IZO (Indium Zinc Oxide) or a metal that transmits visible light, but the embodiments are not limited thereto.

The bank 154 may be arranged to expose the anode electrode 151. The bank 154 may be arranged to define an opening (or a light-emitting area) of the sub-pixel and cover an edge portion (or a border portion) of the anode electrode 151. Each of the sub-pixels may include a red light-emitting area, a green light-emitting area, and a blue light-emitting area. For example, the sub-pixel may be a pixel, but is not limited to the term. The bank 154 may be composed of a material including a black pigment, or an organic material such as a benzocyclobutene resin, a polyimide resin, an acrylic resin, or a photosensitive polymer, but the embodiments are not limited thereto. When the bank 154 is composed of a material including a black pigment or a black dye, it may be a black bank. When the bank 154 is composed of a material including a black pigment or a black dye, it is possible to block light from the outside or light reflected from the outside, thereby further improving the brightness of the display device. A spacer 155 may be further arranged on the bank 154. The spacer may be composed of the same material as the bank 154, but the embodiments are not limited thereto.

The encapsulating part 170 may be arranged on the bank 154 or the light-emitting part 150. The encapsulating part 170 may include one or more insulating layers. For example, the encapsulating part 170 may include a first encapsulating layer 171, a second encapsulating layer 172 on the first encapsulating layer 171, and a third encapsulating layer 173 on the second encapsulating layer 172. The encapsulating part 170 may include one or more inorganic material layers and one or more organic material layers. For example, the first encapsulating layer 171 and the third encapsulating layer 173 may include an inorganic material, and the second encapsulating layer 172 may include an organic material, but the embodiments are not limited thereto.

A touch buffer layer 181 may be arranged on the encapsulating part 170. For example, the touch buffer layer 181 may be arranged on the third encapsulating layer 173. The touch buffer layer 181 may be made of the same material as the buffer layer 102, but the embodiments are not limited thereto. An insulating layer 184 may be arranged on the touch buffer layer 181. The insulating layer 184 may prevent a short between touch electrodes. The insulating layer 184 may be formed of silicon oxide (SiOx), silicon nitride (SiNx), or a multilayer thereof, but the embodiments are not limited thereto. A first touch electrode 185 may be arranged on the insulating layer 184. The first touch electrode 185 may include a first a touch electrode 185a extending in a first direction and a first b touch electrode 185b extending in a second direction different from the first direction.

A second touch electrode 182 may be placed between the touch buffer layer 181 and the insulating layer 184.

The second touch electrode 182 can be electrically connected to the first 1a touch electrode 185a through a contact hole formed in the insulating layer 184. For example, the first 1a touch electrode 185a and the second touch electrode 182 can extend in the first direction.

The first touch electrode 185 and the second touch electrode 182 may include a metal material. For example, they may be made of titanium (Ti), nickel (Ni), aluminum (Al), or an alloy thereof, and may be made of three layers such as titanium (Ti)/aluminum (Al)/titanium (Ti), but the embodiments of the present specification are not limited thereto.

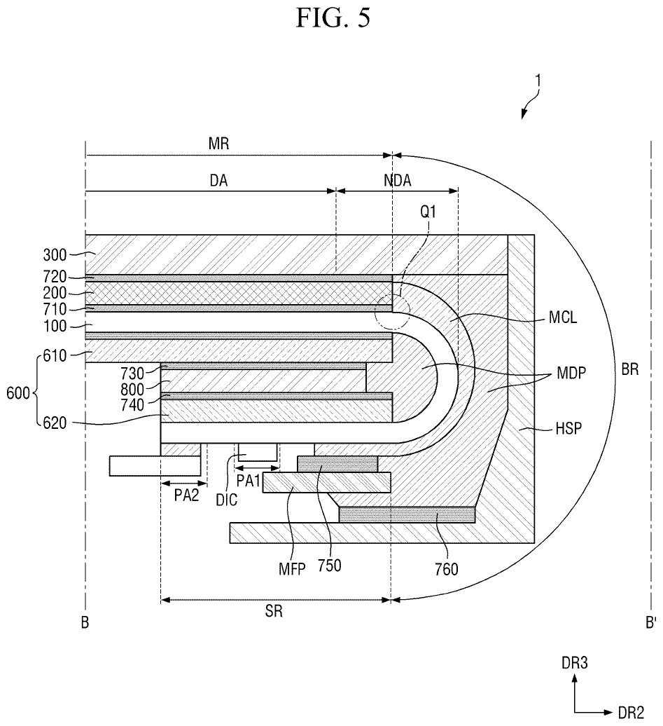

FIG. 5 is a cross-sectional view cut along B-B′ in FIG. 3.

As shown in FIGS. 4 and 5, the display device 1 may include a display panel 100, a planarizing layer 200, a cover layer 300, a back plate layer 600, a plate layer 800, a bonding layer 710, 720, 730, 740, and 750, a cover layer MCL, a mold MDP, a mold frame MFP, and a housing HSP.

The bending region BR of the display panel 100 has a curved shape and can be bent in the thickness direction. The main-region MR and the sub-region SR of the display panel 100 can overlap each other.

The polarizing layer 200 may be arranged on the main-region MR of the display panel 100. The polarizing layer 200 may polarize light emitted from the display panel 100 at a polarization angle. The polarizing layer 200 may emit light polarized at a polarization angle to the outside. The polarizing layer 200 may include a function of blocking reflection of light except for light polarized at a polarization angle among external light. The polarizing layer 200 may include a first phase delay layer, a second phase delay layer on the first phase delay layer, and a polarizing layer on the second phase delay layer. In FIG. 5, the polarizing layer 200 and the display panel 100 are shown as being separate from each other, but the embodiments are not limited thereto and the planarizing layer 200 may be included in the display panel 100.

The cover layer 300 may be arranged on the polarizing layer 200. The cover layer 300 may be formed of a glass material including glass or quartz, but the embodiments are not limited thereto, and may be formed of a plastic material. The cover layer 300 may be arranged on the display panel 100 to protect members arranged under the cover layer 300 from the outside. The cover layer 300 may be a cover layer formed by chemical strengthening, but the embodiments are not limited thereto. The cover layer 300 may be a cover window, a window cover, or a cover member, but the embodiments are not limited thereto.

The cover layer 300 can protect the components placed under the cover layer 300 from the outside, but as described, since the cover layer 300 is formed of a glass material, the cover layer 300 may be damaged by an external force, creating glass fragments. The glass fragments may fly to the outside of the display device 1. According to an embodiment of the present disclosure, to prevent flying of glass fragments due to damage to the cover layer 300 or to improve the durability of the cover layer 300, the display device 1 may further include at least one other layer on the cover layer 300. For example, the display device 1 may further include a film layer or a coating layer on the cover layer 300, but the embodiments are not limited thereto.

The lateral surface of the cover layer 300 may protrude outwardly more than the lateral surface of the display panel 100. For example, the lateral surface of the cover layer 300 may protrude outwardly more than the end surface of the bending region BR of the display panel 100, but the embodiments are not limited thereto.

The backplate layer 600 may be arranged at the bottom of the display panel 100. The backplate layer 600 may be arranged at the bottom of the display panel 100 to support the display panel 100. The backplate layer 600 may include a material capable of supporting the display panel 100. For example, the backplate layer 600 may include polyethylene terephthalate (PET), polyimide (PI), or polycarbonate (PC), but the embodiments are not limited thereto. The backplate layer 600 may keep the curvature of the display panel 100 constant when the display device 1 is folded, and may suppress wrinkles occurring on the upper surface of the display panel 100.

The backplate layer 600 may include a first backplate layer 610 on the main-region MR and a second backplate layer 620 on the sub-region SR. The first backplate layer 610 may be disposed between the main-region MR of the display panel 100 and the plate layer 800, and the second backplate layer 620 may be disposed between the sub-region SR of the display panel 100 and the plate layer 800. The backplate layer 600 may not be disposed on the bending region BR.

The plate layer 800 may be placed between the first backplate layer 610 and the second backplate layer 620. The plate layer 800 may include metal. For example, the plate layer 800 may include stainless steel, but the embodiments are not limited thereto.

Additional bonding layers may be arranged between the above-described members 100, 200, 300, 600, and 800. The bonding layers may include a first bonding layer 710, a second bonding layer 720, a third bonding layer 730, a fourth bonding layer 740, a fifth bonding layer 750, and a sixth bonding layer 760.

The first bonding layer 710 may be placed between the display panel 100 and the polarizing layer 200. The first bonding layer 710 may connect or bond the display panel 100 and the polarizing layer 200.

The second bonding layer 720 may be placed between the polarizing layer 200 and the cover layer 300. The second bonding layer 720 may connect or bond the polarizing layer 200 and the cover layer 300.

The third bonding layer 730 may be placed between the first backplate layer 610 and the display panel 100. The third bonding layer 730 may connect or bond the first backplate layer 610 and the display panel 100.

The fourth bonding layer 740 may be placed between the second backplate layer 620 and the plate layer 800. The fourth bonding layer 740 may connect or bond the second backplate layer 620 and the plate layer 800.

The fifth bonding layer 750 may be arranged between the mold frame MFP and the cover layer MCL. The fifth bonding layer 750 may connect or bond the mold frame MFP and the cover layer MCL.

The sixth bonding layer 760 may be arranged between the mold MDP and the housing HSP. The sixth bonding layer 760 may connect or bond the mold MDP and the housing SP.

The first bonding layer 710 and the second bonding layer 720 may each include a transparent adhesive, but the embodiments are not limited thereto. For example, the transparent adhesive may be a transparent resin (OCR) or a transparent adhesive (OCA), but the embodiments are not limited thereto. The third bonding layer 730, the fourth bonding layer 740, the fifth bonding layer 750, and the sixth bonding layer 760 may each include a pressure sensitive adhesive (PSA), but the embodiments are not limited thereto.

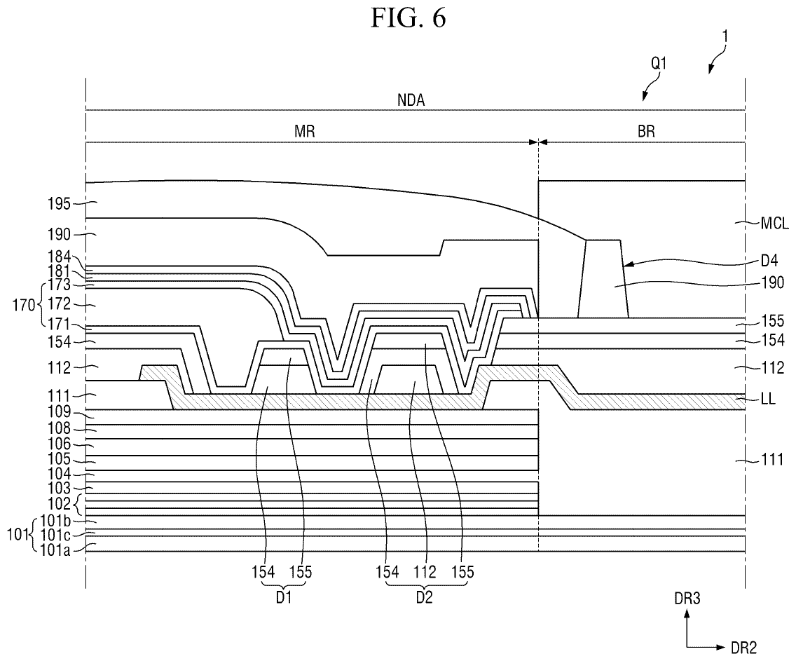

The cover layer MCL may be arranged on one side of the bending region BR of the display panel 100. The cover layer MCL includes a plastic material and may be coated on one side of the bending region BR of the display panel 100 to cover the bending region BR of the display panel 100. A link line (e.g., see LL of FIG. 6) may be arranged on the bending region BR. The cover layer MCL may protect the link line LL from external impact while preventing moisture penetration into the link line LL. In addition, the cover layer MCL may serve to position the link line LL in a neutral plane when the bending region BR of the display panel 100 is bent into a curved shape having a constant radius of curvature. Within the bending region BR, a neutral plane is formed where the tensile force and the compressive force are zero, and the link line LL is positioned on the neutral plane, so that when the display panel 100 is bent, the link line LL receives a bending stress of zero, and thus the display panel 100 can be bent without being damaged by the bending stress.

The cover layer MCL can be in contact with the lateral surfaces of the polarizing layer 200 and the first bonding layer 710. The cover layer MCL can partially extend to the sub-region SR. On the sub-region SR, the cover layer MCL can be bonded to the mold frame MFP through the fifth bonding layer 750.

The data driver DIC may be placed in a first pad area PA1 of the sub-region (SR), and the printed circuit board FPCB may be placed in a second pad area PA2. The printed circuit board FPCB may be electrically connected to pads on the display panel 100 through an anisotropic conductive film ACF. The cover layer MCL may not overlap with the data driver DIC, but the embodiments are not limited thereto.

The mold frame MFP may be placed under the cover layer MCL. The mold frame MFP and the cover layer MCL may be combined through the fifth bonding layer 750.

The mold MDP may be placed on the cover layer MCL. The mold MDP may cover the outer surface of the bending region BR of the display panel 100. For example, the mold MDP may be in direct contact with the cover layer MCL, the lower surface of the cover layer 300, the lateral surface of the fifth bonding layer 750, the upper surface, the lateral surface, and the lower surface of the mold frame MFP. The mold MDP may also be in contact with the inner surface of the housing HSP. The mold MDP may also be placed on the inner side of the bending region BR. The mold MDP may be in contact with the inner surface of the bending region BR, the lateral surfaces of the first and second backplate layers 610 and 620), and the lateral surface of the plate layer 800.

The housing HSP may be placed on the outermost side of the display device 1. A portion of the housing HSP extending in the thickness direction (or the third direction DR3) may be in direct contact with the cover layer 300 and the mold MDP. A portion of the housing HSP extending in the second direction DR2 may be bonded to the mold MDP through the sixth bonding layer 760.

FIG. 6 is an enlarged cross-sectional view of area Q1 shown in FIG. 5. FIG. 6 shows the main-region MR and the benign region BR of the display device 1 together. The bending region BR of FIG. 5 is a region having a curved shape, but for convenience of explanation, the bending region BR of FIG. 6 is expressed as flat.

As shown in FIGS. 4, 5, and 6, the panel weapon layers 102, 103, 104, 105, 106, 108, and 109 may not be arranged in the bending region BR. Accordingly, the first protective layer 111 may be in direct contact with the substrate 101 in the bending region BR.

The link line LL may be arranged on the first protective layer 111. The link line LL may be a line connecting a pad (or data pad) connected to the data driver DIC of FIG. 5 and a data line in the display area DA. The link line LL may be located on the same layer as the connection electrode 145 of FIG. 4, but the embodiments of the present specification are not limited thereto, and the link line LL may be located on the same layer as the first source electrode 121. The link line LL may be in contact with the lateral surface of the first protective layer 111 on the main-region MR and may be in contact with a portion of the upper surface, but the embodiments are not limited thereto. In the present disclosure, being located in the same layer may include the concept of including the same material.

The second protective layer 112 may be placed on the link line LL. The second protective layer 112 may be placed on the main-region MR and the bending region BR. The second protective layer 112 on the main-region MR may be in direct contact with the end of the link line LL.

Two dams D1 and D2 may be arranged in the main-region MR adjacent to the bending region BR. The first dam D1 may be arranged between the display area DA and the bending region BR, and the second dam D2 may be arranged between the first dam D1 and the bending region BR. Although only two dams D1 and D2 are shown in FIG. 6, the embodiments are not limited thereto, and one or three or more dams may be arranged.

The second protective layer 112 can constitute the first layer of the second dam D2. The second protective layer 112 can be arranged across the main-region MR and the bending region BR. The second protective layer 112 of the second dam D2 can be in direct contact with a metal pattern 151a located on the same layer as the anode electrode (see 151 of FIG. 4). The upper surface of the metal pattern 151a can be in direct contact with a bank 154 of the second dam D2 to be described later.

A bank (154) may be arranged on the second protective layer 112. The bank 154 may be arranged on the main-region MR and the bending region BR. In the main-region MR, the bank 154 may constitute the first layer of the first dam D1 and the second layer of the second dam D2. In the second dam D2, the bank 154, which is the second layer, may be arranged to cover the second protective layer 112, which is the first layer, but the embodiments are not limited thereto. For example, the two-layered bank 154 may cover the upper surface of the first layer, the second protective layer 112, completely cover the lateral surface on one side in the second direction DR2, and partially cover the lateral surface on the other side in the second direction DR2, but the embodiments are not limited thereto. The bank 154 may be in direct contact with the upper surface of the metal pattern 151a. Although the present disclosure exemplifies that the spacer 155 does not constitute the dams D1 and D2, the present disclosure is not limited thereto, and the spacer 155 may be additionally arranged on at least one of the dams D1 and D2.

The spacer 155 may be placed on the bank 154. The spacer 155 may be placed on the main-region MR and the bending region BR.

The encapsulating part 170 may be disposed on the spacer 155. The first encapsulating layer 171 may be disposed on the main-region MR, but not on the bending region BR. The first encapsulating layer 171 may be in direct contact with the first damp D1 and the second dam D2. The second encapsulating layer 172 may be terminated by the first dam D1. The third encapsulating layer 173 may be arranged in the main-region MR but not in the bending region BR. The third encapsulating layer 173 may be in direct contact with the first encapsulating layer 171 on the first dam D1 and the second dam D2.

A touch inorganic film may be disposed on the encapsulating part 170. The touch inorganic film may be in the main-region MR, but not in the bending region BR. The touch inorganic film may include a touch buffer layer 181 and a touch insulating layer 184.

The touch organic layer 190 may be disposed on the touch insulating layer 184. The first touch organic layer 190 may be formed of an organic material including an acrylic resin, an epoxy resin, a phenolic resin, a polyamide resin, or a polyimide resin, but the embodiments are not limited thereto.

The first touch organic layer 190 may be disposed in the main-region MR, and form a third dam D3 in the bending region BR. The third dam D3 may be directly disposed on the spacer 155 and spaced a preset distance from the boundary of the main-region MR, but the embodiments are not limited thereto. The third dam D3 may be a touch organic layer dam. In the third dam D3, the second touch organic layer 195 may be terminated. The second touch organic layer 195 may be in direct contact with the lateral surface of the third dam D3.

The second touch organic layer 195 may be disposed on the first touch organic layer 190. The second touch organic layer 195 may be formed of an organic material including an acrylic resin, an epoxy resin, a phenolic resin, a polyamide resin, or a polyimide resin, but the embodiments are not limited thereto.

In the bending region BR, the second touch organic layer 195 may be in direct contact with the lateral surface of the third dam D3, the upper surface of the spacer k155, and the lateral surface of the first touch organic layer 190.

A cover layer MCL may be disposed on the second touch organic layer 195. The cover layer MCL may be disposed in the bending region BR, but not in the main-region MR. The cover layer MCL may be in direct contact with the upper surface of the third dam D3, the upper surface of the second touch organic layer 195, and the upper surface of the spacer 155.

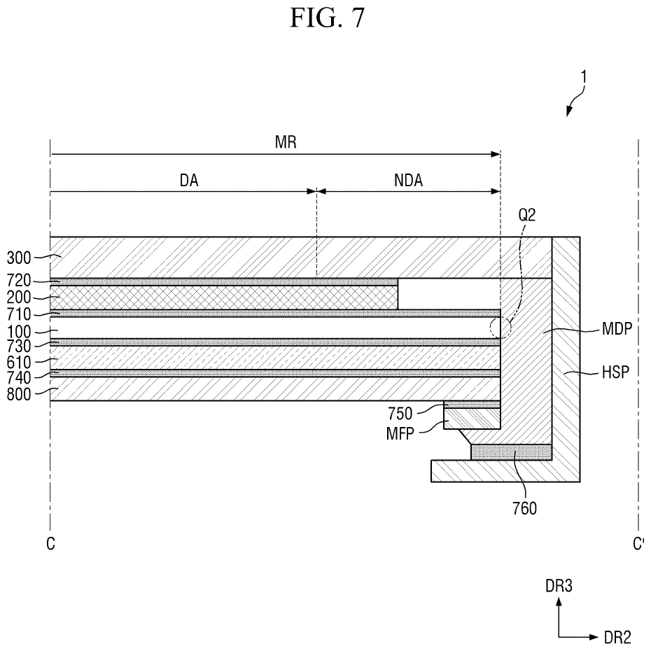

FIG. 7 is a cross-sectional view cut along C-C′ in FIG. 3. FIG. 7 shows the main-region MR including the display area DA and the non-display area NDA. FIG. 7 exemplifies a cross-sectional view showing the right region of the display device 1. The cross-sectional view of the right region of the display device 1 may be substantially identical to the cross-sectional views of the left region and upper region of the display device 1.

As shown in FIGS. 4 to 7, the mold MDP may be in direct contact with the lateral surface of the display panel 100, the lateral surface of the backplate layer 610, and the lateral surface of the plate layer 800. The mold MDP may be in direct contact with the lateral surface and lower surface of the mold frame MFP. The mold MDP may be coupled to the housing HSP through the sixth bonding layer 760. The mold MDP may become in contact with the lower surface of the cover layer 300 and the inner surface of the housing HSP.

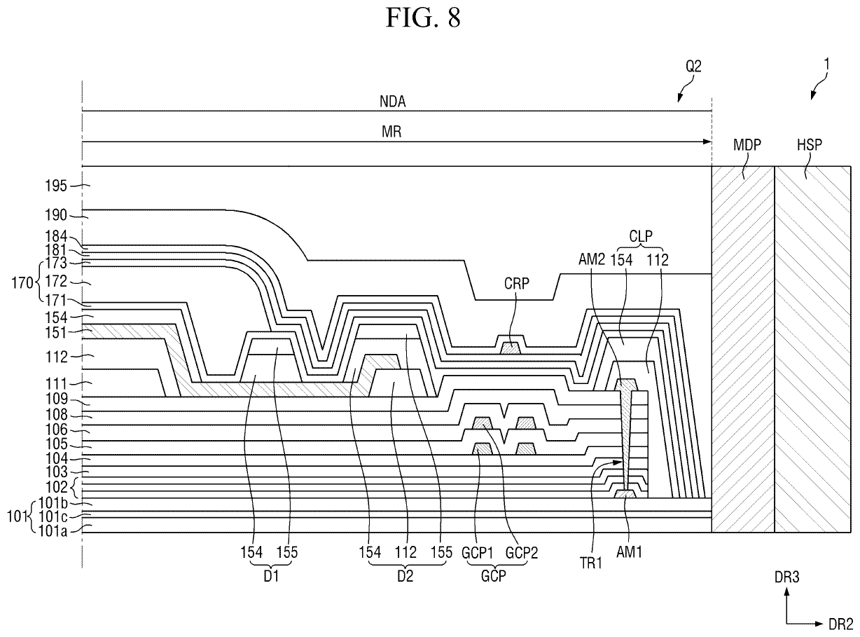

FIG. 8 is an enlarged cross-sectional view of area Q2 shown in FIG. 7.

As shown in FIGS. 4 to 8, the lateral surface of the display panel 100 may be in direct contact with the mold MDP, and the mold DMP may include an organic material that is greatly deformed (or expanded or shrunk) by heat. Accordingly, the lateral surface of the display panel 100 may be vulnerable to rigidity. Since the lateral surface of the display panel 100 is vulnerable to rigidity, film lifting or film peeling might occur near the lateral surface of the display panel 100. In addition, since film peeling or film lifting could occur near the lateral surface of the display panel 100, there is a very high possibility that cracks will occur near the lateral surface of the display panel 100. The lateral surface of the display panel 100 may be a trimmed surface.

As shown in FIG. 8, the display panel (100, see FIG. 7) according to one embodiment may further include a clad part CLP. The clad part CLP may be configured of a second protective layer 112 that is a first layer, and a bank 154 that is a second layer. However, the embodiments are not limited thereto, and the first protective layer 111 or the spacer 155 may further form the clad part CLP. At least one panel inorganic layer 102, 103, 104, 105, 106, 108, and 109 may not be in contact with the mold MDP. The second protective layer 112 of the clad part CLP may be in direct contact with the lateral surface of the at least one panel inorganic layer 102, 103, 104, 105, 106, 108, and 109, and the upper surface of the substrate 101. The second substrate portion 101b of the substrate 101 may include an organic material and the clad part CLP may include an organic material. Due to that, the second protective layer 112 of the clad part CLP and the second substrate portion 101b may be in direct contact, thereby improving film lifting between the at least one panel inorganic layer 102, 103, 104, 105, 106, 108, and 109.

The first encapsulating layer 171 and the second encapsulating layer 173 may extend to the outside of the clad part CLP, and not become into contact with the mold MDP. The first encapsulating layer 171 and the second encapsulating layer 173 may each in contact with the substrate 101, but the embodiments are not limited thereto. The touch buffer layer 181 and the touch insulating layer 184 may extend to the outside of the clad part CLP, and not come into contact with the mold MDP. The touch buffer layer 181 and the touch insulating layer 184 may each be in contact with the substrate 101, but the embodiments are not limited thereto.

Meanwhile, crack-preventing patterns GCP1 and CCP2 may be further disposed between the clad part CLP and the second dam D2. The gate crack preventing patterns GCP1 and GCP2 may include a first gate crack preventing pattern GCP1 provided on the same layer as the first gate electrode (122, see FIG. 6), and a second gate crack preventing pattern GCP2 provided on the same layer as the second light-blocking layer (136, see FIG. 6). In addition, a crack detecting pattern CRP may be further provided on the gate crack preventing pattern GCP1 and CGP2. The crack detecting pattern CRP may be provided on the same layer as the second touch electrode (182, see FIG. 6), but the embodiments are not limited thereto. In some embodiments, the gate crack preventing patterns GCP1 and GCP2 may be omitted. In this instance, there is an advantage that the clad part CLP can expand more toward the second dam D2.

According to one embodiment, a stop hole may be formed in the at least one of the panel weapon layers 102, 103, 104, 105, 106, 108, and 109 or the at least one of the touch inorganic layers 181 and 184. The stop hole may overlap the clad part CLP. The at least one of the panel inorganic layers 102, 103, 104, 105, 106, 108, and 109 according to one embodiment may have a first stop hole TR1 formed therein. The first stop hole TR1 may completely penetrate the panel inorganic layers 102, 103, 104, 105, 106, 108, and 109 in the thickness direction. An attachment metal may be further arranged on the first stop hole TR1. The attachment metal may include a first attachment metal AM1 and a second attachment metal AM2. The first attachment metal AM1 may be positioned on the same layer as the first gate electrode (122, see FIG. 6) and may include the same material, and the second attachment metal AM2 may be positioned on the same layer as the second light-blocking layer 136 and may include the same material. The first attachment metal AM1 can be disposed between the buffer layer 102 and the substrate 101, and the second attachment metal AM2 can be disposed between the sixth insulating layer 109 and the first protective layer 111. The first stop hole TR1 can partially expose the upper surface of the first attachment metal AM1, and the second attachment metal AM2 can directly contact the first attachment metal AM1 within the first stop hole TH1. The second protective layer 112 of the clad part CLP may be in direct contact with the second attachment metal AM2 and may completely cover the second attachment metal AM2, but the embodiments are not limited thereto. The second attachment metal AM2 may be in direct contact with lateral surfaces of the panel inorganic layers 102, 103, 104, 105, 106, 108, and 109 exposed by the first stop hole TR1 within the first stop hole TR1.

In the display device 1 according to an example embodiment, a first stop hole TR1 may be formed on the clad part CLP. As a result, a separate stop hole may not be formed on the inner side of the clad part (CLP) (or in the non-display area NDA between the clad part CLP and the display area DA, thereby achieving a narrow bezel. In addition, since the first stop hole TR1 is formed in the clad part CLP located at the outermost side of the display panel, cracks at the end of the display panel caused by external force can be blocked at the outermost end.

In addition, by blocking the crack at the end of the display panel through the first stop hole TR1 at the outermost end, moisture penetration into the display area DA through the crack is improved, thereby improving the lifespan.

The first attachment metal AM1 overlapping the clad part CLP and the second attachment metal AM2 in direct contact with the first attachment metal AM1 within the first stop hole (TR1) may be further provided, and the second attachment metal AM2 may directly contact the lateral surface of the inorganic layers 102, 103, 104, 105, 106, 108, and 109 exposed by the first stop hole TR1, thereby solve peeling or lifting between the inorganic layers 102, 103, 104, 105, 106, 108, and 109. In addition, since the lower surface of the second attachment metal AM2 is in direct contact with the first attachment metal AM1, and the lower surfaces of the inorganic layers 102, 103, 104, 105, 106, 108, and 109 are supported by the first attachment metal AM1, peeling or lifting between the inorganic layers 102, 103, 104, 105, 106, 108, and 109 can be further improved.

Hereinafter, a display according to other example embodiments will be described. In the following embodiments, detailed descriptions or repeated descriptions of the numeral references or configurations described in FIGS. 1 to 8 may be omitted.

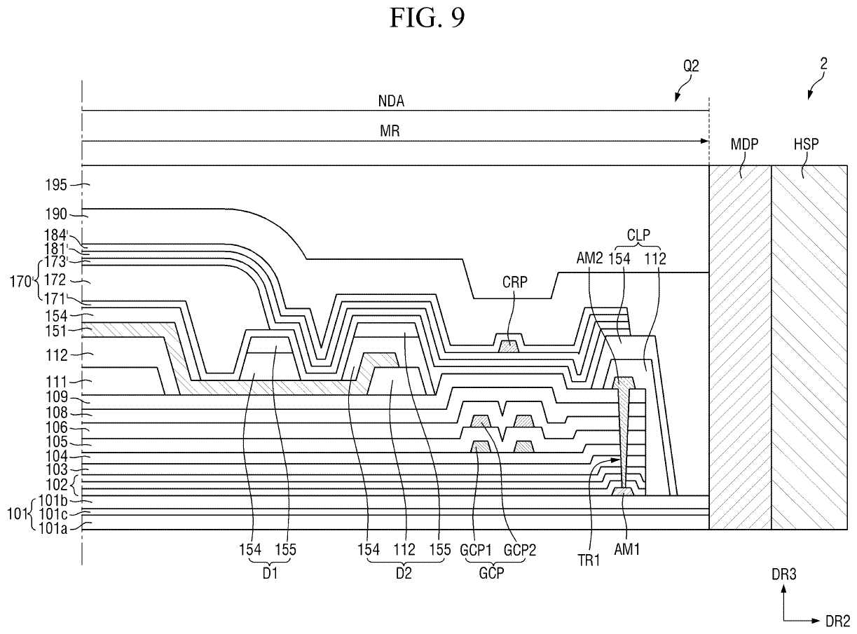

FIG. 9 is a cross-sectional view of a display device according to another example embodiment.

As shown in FIG. 9, the display device 2 according to this example embodiment is different from the example display device 1 according to FIG. 8 in that the first encapsulating layer 171′, the third encapsulating layer 173′, the touch buffer layer 181′ and the touch insulation layer 184′ terminate on the upper surface of the clad part CLP.

More specifically, the first encapsulating layer 171′, the third encapsulating layer 173′, the touch buffer layer 181′, and the touch insulating layer 184′ can be terminated on the upper surface of the clad part CLP. That is, the lateral surfaces of the first encapsulating layer 171′, the third encapsulating layer 173′, the touch buffer layer 181′, and the touch insulating layer 184′ can be arranged on the upper surface of the clad part CLP. When the inorganic layers are arranged close to the mold MDP, cracks occurring around the mold MDP can easily propagate to the inorganic layers. However, according to this embodiment, since the first encapsulating layer 171′, the third encapsulating layer 173′, the touch buffer layer 181′, and the touch insulation layer 184′ terminate on the upper surface of the clad part CLP, there is an advantage that cracks propagating to the third encapsulating layer 173′, the touch buffer layer 181′, and the touch insulating layer 184′ can be minimized.

Other detailed descriptions are omitted as they are described above in FIG. 8.

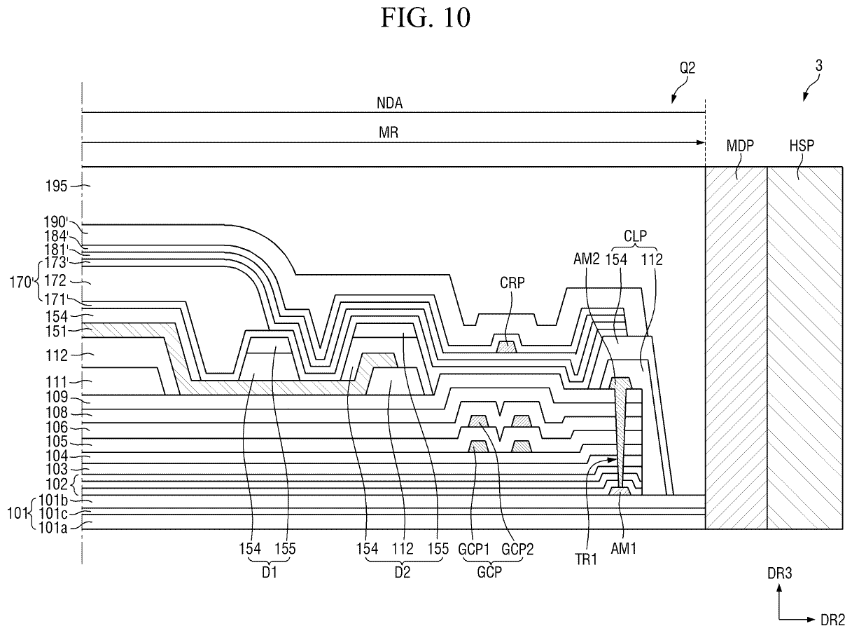

FIG. 10 is a cross-sectional view of a display device according to a further example embodiment.

As shown in FIG. 10, the display device 3 according to this example embodiment is different from the example display device 2 according to FIG. 9 in that the first touch organic layer 190′ can terminate on the clad part CLP.

More specifically, the first touch organic layer 190′ may end on the clad part CLP. As shown in FIG. 8, when the first and second touch organic layers 190 and 195 each extend to the outer side of the clad part CLP, film lifting between the first touch organic layer 190 and the second touch organic layer 195 may occur on the side of the clad part CLP.

However, in the display device 3 according to this example embodiment, there is an advantage that the first touch organic layer 190′ ends on the clad part CLP and the second touch organic layer 195 covers the lateral surface of the first touch organic layer 190′, thereby preventing film lifting between the first touch organic layer 190′ and the second touch organic layer 195.

Other detailed descriptions are omitted as they are described above in FIGS. 8 and 9.

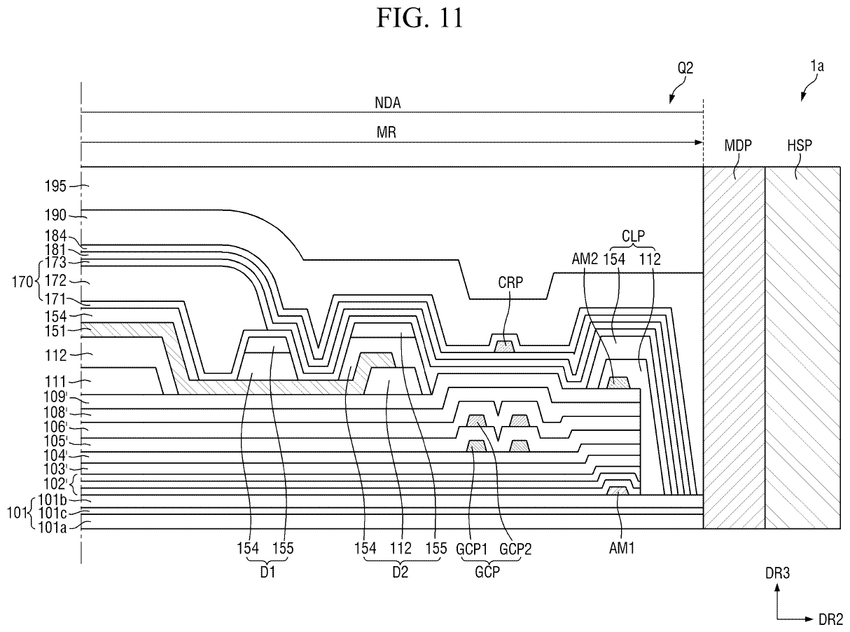

FIG. 11 is a cross-sectional view of a display device according to a comparative example.

As shown in FIGS. 8 and 11, in the display device 1a according to the comparative example, the first stop hole TR1 may not be formed in at least one panel inorganic layer 102′_1, 103′_1, 104′_1, 105′_1, 106′_1, 108′_1, and 109′_1.

As shown in FIG. 11, the lateral surface of the substrate 101 and the lateral surface of the second touch organic layer 195 are in direct contact with the mold MDP, and since the mold MDP is greatly deformed (or expanded or shrunk) by heat, the lateral surface of the display panel (100, see FIG. 1) may be vulnerable to rigidity.

However, as described above in FIG. 8, the display device 1 according to an example embodiment may further include the first stop hole TR1 that is formed in one of the panel inorganic layers 102, 103, 104, 105, 106, 108, and 109, and the first attachment metal AM1 overlapping the clad portion (CLP) and the second attachment metal AM2 directly in contact with the first attachment metal AM1 within the first stop hole TR1. The second attachment metal AM2 can improve peeling or lifting between the inorganic layers 102, 103, 104, 105, 106, 108, and 109 by making direct contact with the lateral surfaces of the inorganic layers 102, 103, 104, 105, 106, 108, and 109 exposed by the first stop hole TR1. In addition, since the lower surface of the second attachment metal AM2 is in direct contact with the first attachment metal AM1, and the lower surfaces of the inorganic layers 102, 103, 104, 105, 106, 108, and 109 are supported by the first attachment metal AM1, peeling or lifting between the inorganic layers 102, 103, 104, 105, 106, 108, and 109 can be further improved.

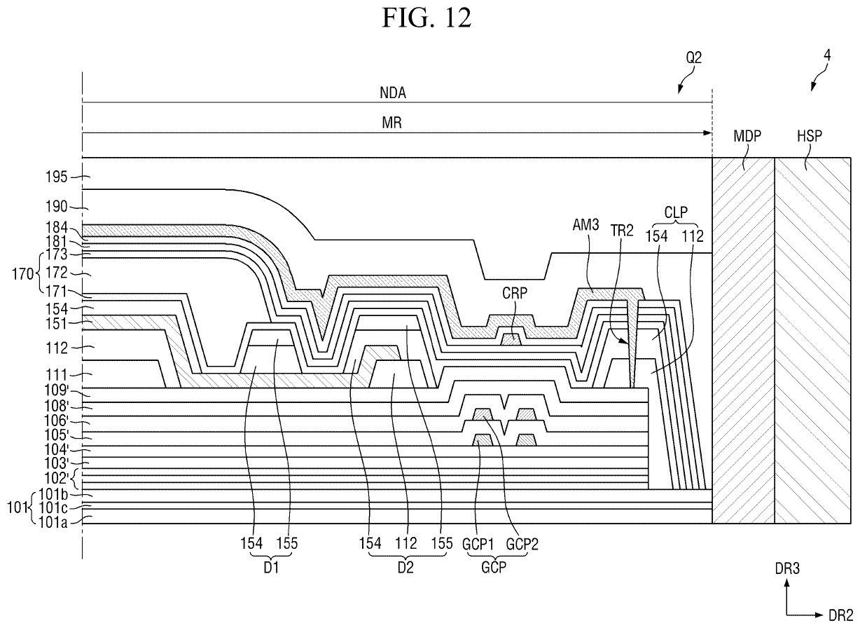

FIG. 12 is a cross-sectional view of a display device according to a further example embodiment.

As shown in FIG. 12, the display device 4 according to this example embodiment is different from the example display device 1 according to FIG. 8 in that it includes a second stop hole TR2.

More specifically, the second stop hole TR2 may overlap the clad part CLP. The second stop hole TR2 may penetrate at least one of the touch inorganic layers 181 and 184 and the third encapsulating layer 173 in the thickness direction. A third attachment metal AM3 may be arranged within the second stop hole TR2. The third attachment metal AM3 may be positioned on the same layer as the first touch electrode 185 and may include the same material as the first touch electrode 185. The second stop hole TR2 may terminate at the upper surface of the bank 154 of the clad part CLP. The third attachment metal AM3 may be in direct contact with the upper surface of the bank 154 of the clad part CLP within the second stop hole TR2 and may be in direct contact with the inner surface of the touch inorganic layers 181 and 184 and the third encapsulating layer 173. The third attachment metal AM3 can extend to at least one of the dams D1 and D2. For example, the third attachment metal AM3 can overlap the first dam D1, the second dam D2, and the gate crack preventing pattern GCP1 and GCP2 in the thickness direction. The third attachment metal AM3 can overlap the crack detecting pattern CRP in the thickness direction.

In the display device 4 according to this example embodiment, the second stop hole TR2 can be formed on the clad part CLP. As a result, a separate stop hole does not have to be formed on the inner surface of the clad part CLP (or the non-display area NDA between the clad part CLP and the display area DA, thereby achieving a narrow bezel. In addition, since the second stop hole TR2 is formed in the clad part CLP located at the outermost side of the display panel, cracks at the end of the display panel caused by external force can be blocked at the outermost end.

In addition, by blocking the crack at the end of the display panel through the second stop hole TR2 at the outermost end, moisture penetration into the display area DA through the crack is improved, thereby improving the lifespan.

It further includes a third attachment metal AM3 overlapping the clad part CLP, and the third attachment metal AM3 can improve peeling or lifting between the inorganic layers 171, 181, and 184 by directly contacting the lateral surface of the inorganic layers 171, 181, and 184 exposed by the second stop hole TR2.

In addition, the third attachment metal AM3 may overlap the first dam D1 and the second dam D2, and on the lateral surface of the dam D1 and D2, the first touch organic layer 190 may be lifted from the second touch organic layer 195 due to the inclination of the dam D1 and D2. The film lifting between the touch organic layers 190 and 195 may cause cracks. However, in the display device 4 according to the present embodiment, since the third attachment metal AM3 is arranged to overlap the first dam D1 and the second dam D2, there is an advantage in that cracks occurring due to lifting between the touch organic layers 190 and 195 on the dams D1 and D2 can be prevented.

Other detailed descriptions are omitted as they are described above in FIG. 8.

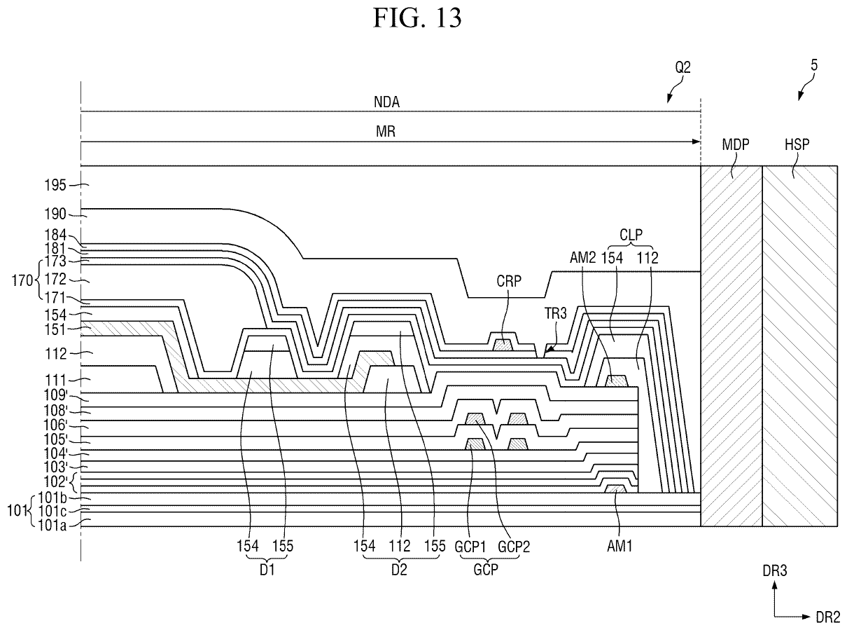

FIG. 13 is a cross-sectional view of a display device according to a still further example embodiment.

As shown in FIG. 13, the display device 5 according to this example embodiment is different from the example display device 1 according to FIG. 8 in that the third stop hole TR3 can be positioned between the clad part CLP and the second dam D2.

More specifically, the third stop hole TR3 can penetrate the touch weapon layers 181_2 and 184_2 in the thickness direction. The third stop hole TR3 can terminate on the upper surface of the third encapsulating layer 173. The third stop hole TR3 can be located between the crack detecting pattern CRP and the clad part CLP, but the embodiments are not limited thereto. The first touch organic layer 190 can be filled within the third stop hole TR3, and the first touch organic layer 190 can be in direct contact with the third encapsulating layer 173 within the third stop hole TR3.

According to this example embodiment, since the third stop hole TR3 is formed in the touch inorganic layers 181_2 and 184_2, cracks at the end of the display panel caused by external force can be blocked in front of the display area (DA, see FIG. 1).

Other detailed descriptions are omitted as they are described above in FIG. 8.

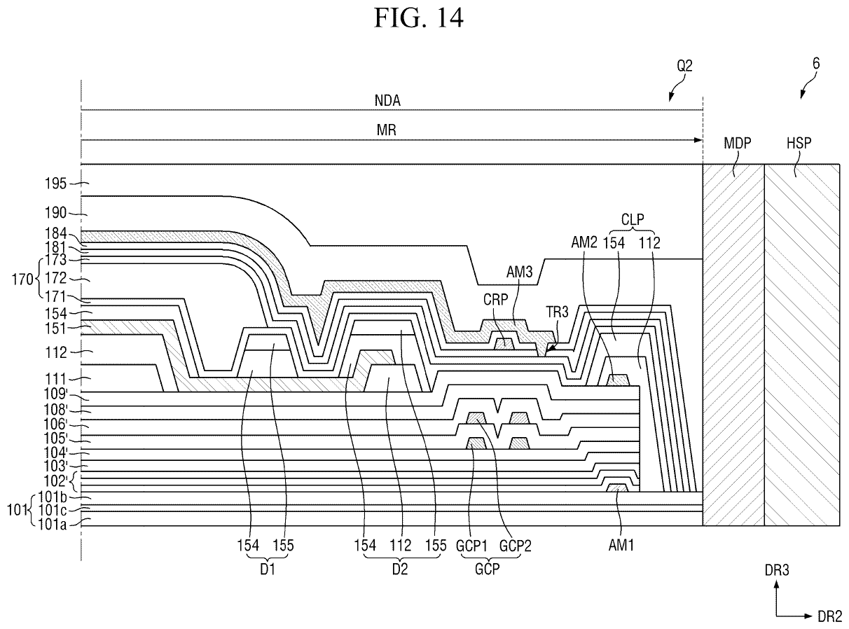

FIG. 14 is a cross-sectional view of a display device according to a still further example embodiment.

As shown in FIG. 14, the display device 6 according to this example embodiment is different from the example display device 5 according to FIG. 13 in that it further includes a third attachment metal AM3 arranged within the third stop hole TR3.

The third attachment metal AM3 may be placed within the third stop hole TR3. The third attachment metal AM3 may be positioned on the same layer as the first touch electrode 185 and may include the same material as the first touch electrode 185. The third attachment metal AM3 may be in direct contact with the inner surface of the touch inorganic layers 181 and 184 within the second stop hole TR2. The third attachment metal AM3 may extend to at least one dam D1 and D2. For example, the third attachment metal AM3 can overlap the first dam D1, the second dam D2, and the gate crack preventing pattern GCP1 and GCP2 in the thickness direction. The third attachment metal AM3 can overlap the crack detecting pattern CRP in the thickness direction.

According to this example embodiment, the third attachment metal AM3 is further placed within the third stop hole TR3. The third attachment metal AM3 is in direct contact with the lateral surface of the inorganic layers 181 and 184 exposed by the third stop hole TR3, thereby improving peeling or lifting between the inorganic layers 181 and 184.

In addition, the third attachment metal AM3 may overlap the first dam D1 and the second dam D2, and on the lateral surface of the dams D1 and D2, the first touch organic layer 190 may be lifted from the second touch organic layer 195 due to the inclination of the dams D1 and D2. The film lifting between the touch organic layers 190 and 195 may cause cracks. However, in the display device 6 according to this embodiment, since the third attachment metal AM3 is arranged to overlap the first dam D1 and the second dam D2, there is an advantage in that cracks occurring due to lifting between the touch organic layers 190 and 195 on the dams D1 and D2 can be prevented.

Other detailed descriptions are omitted as they are described above in FIG. 13.

The display device according to various example embodiments may be described as follows.

The display device according to the embodiments may include a substrate comprising a display area including a pixel, and a non-display area disposed adjacent to the display area; at least one panel inorganic layer on the substrate; a clad part disposed on the at least one panel inorganic layer in the non-display area and configured to cover an end of the at least one panel inorganic layer; and a touch part disposed on the clad part and comprising at least one touch inorganic layer and a touch electrode on the at least one touch inorganic layer. The at least one panel inorganic layer or the at least one touch inorganic layer may include a stop hole overlapping the clad part.

The display device may further include a dam disposed between the clad part and the display area.

The display device may further include a first transistor on the substrate in the display area; and a second transistor between the first transistor and the touch part, and a source electrode of the first transistor and a source electrode of the second transistor may be disposed on the same layer.

The display device according to the embodiments of the present disclosure may further include a first protective layer between the second transistor and the touch part; a connecting electrode between the first protective layer and the touch part; a second protective layer between the connecting electrode and the touch part; and a light emitting part between the second protective layer and the touch part. The connecting electrode may be configured to electrically connect an anode electrode of the light emitting part and a source electrode of the second transistor.

The display device according to the embodiments of the present disclosure may further include a bank on the anode electrode, and the clad part may be configured of the second protective layer and the bank.

The display device according to the embodiments of the present disclosure further include an encapsulating part between the light emitting part and the touch part. The encapsulating part may include a first encapsulating layer, a second encapsulating layer on the first encapsulating layer, and a third encapsulating layer on the second encapsulating layer, and the second encapsulating layer may terminate on the dam.

In the display device according to the embodiments of the present disclosure, the at least one panel inorganic layer may overlap the clad part, and include a first stop hole penetrating in the thickness direction.

The display device according to the embodiments of the present disclosure may further include a first attachment metal between the substrate and the at least one panel inorganic layer; and a second attachment metal between the at least one panel inorganic layer and the clad part. The first attachment metal and the second attachment metal may be in direct contact with each other.

In the display device according to the embodiments of the present disclosure, the second attachment metal may be in contact with the first attachment metal in the first stop hole, and in direct contact with the at least one panel inorganic layer.

The display device according to the embodiments of the present disclosure further include a light-blocking layer between the first transistor and the substrate. The first attachment metal may be disposed on the same layer as the light-blocking layer, and the second attachment metal may be disposed on the same layer as a source electrode or drain electrode of the first transistor.

In the display device according to the embodiments of the present disclosure, the at least one touch inorganic layer and the third encapsulating layer may include a second stop hole overlapping the clad part and penetrated in a thickness direction.

In the display device according to the embodiments of the present disclosure, the at least one touch inorganic layer may include a touch buffer layer on the encapsulating part, and a touch insulating layer, and the touch electrode may include a first touch electrode on the touch insulating layer and a second touch electrode between the touch buffer layer and the touch insulating layer. The display device according to the embodiments of the present disclosure may further include a third attachment metal disposed within the second stop hole, and the third attachment metal may be in direct contact with the clad part.

In the display device according to the embodiments of the present disclosure, the third attachment metal may be disposed on the same layer as the first touch electrode.

In the display device according to the embodiments of the present disclosure, the third attachment metal may overlap the dam.

In the display device according to the embodiments of the present disclosure, the touch part may further include a first touch organic layer on the touch electrode, and a second touch organic layer on the first touch organic layer. The display device may further include a mold that is in contact with a lateral surface of the substrate, a lateral surface of a first touch organic layer, and a lateral surface of a second touch organic layer.

In the display device according to the embodiments of the present disclosure, the clad part may be in direct contact with the substrate.

In another aspect, a display device according to the embodiments of the present disclosure may include a substrate comprising a display area including a pixel, and a non-display area disposed adjacent to the display area; at least one panel inorganic layer on the substrate; a clad part disposed on the at least one panel inorganic layer in the non-display area and configured to cover an end of the at least one panel inorganic layer; a dam disposed between the clad part and the display area; and a touch part disposed on the clad part and the dam, and comprising at least one touch inorganic layer and a touch electrode on the at least one touch inorganic layer. The at least one touch inorganic layer may include a stop hole, and the stop hole may be disposed between the clad part and the dam.

In the display device according to the embodiments of the present disclosure, the touch part may further include a first touch organic layer on the touch electrode, and a second touch organic layer on the first touch organic layer. The display device may further include a mold in contact with a lateral surface of the substrate, a lateral surface of the first touch organic layer, and a lateral surface of the second touch organic layer.

The display device according to the embodiments of the present disclosure may further include an encapsulating part between the clad part and the touch part, and the first touch organic layer may be in direct contact with the encapsulating part in the stop hole.

In the display device according to the embodiments of the present disclosure, the clad part may be in direct contact with the substrate.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. Further, even where the operating effects according to an example configuration of the present disclosure are not explicitly described while describing an example embodiment of the present disclosure, it should be appreciated that predictable effects can be recognized by the configuration.

What is claimed is:

1. A display device, comprising:
a substrate comprising a display area including a pixel, and a non-display area disposed adjacent to the display area;
at least one panel inorganic layer on the substrate;
a clad part disposed on the at least one panel inorganic layer in the non-display area and configured to cover an end of the at least one panel inorganic layer; and
a touch part disposed on the clad part and comprising at least one touch inorganic layer and a touch electrode on the at least one touch inorganic layer,
wherein the at least one panel inorganic layer or the at least one touch inorganic layer comprises a stop hole overlapping the clad part.

2. The display device of claim 1, further comprising:
a dam disposed between the clad part and the display area.

3. The display device of claim 2, further comprising:
a first transistor on the substrate in the display area; and
a second transistor between the first transistor and the touch part,
wherein a source electrode of the first transistor is disposed on a same layer as a source electrode of the second transistor.

4. The display device of claim 3, further comprising:
a first protective layer between the second transistor and the touch part;
a connecting electrode between the first protective layer and the touch part;
a second protective layer between the connecting electrode and the touch part; and
a light emitting part between the second protective layer and the touch part,
wherein the connecting electrode is configured to electrically connect an anode electrode of the light emitting part and the source electrode of the second transistor.

5. The display device of claim 4, further comprising:
a bank on the anode electrode,
wherein the clad part is configured of the second protective layer and the bank.

6. The display device of claim 5, further comprising:
an encapsulating part between the light emitting part and the touch part,
wherein the encapsulating part comprises a first encapsulating layer, a second encapsulating layer on the first encapsulating layer, and a third encapsulating layer on the second encapsulating layer, and
wherein the second encapsulating layer terminates on the dam.

7. The display device of claim 6, wherein the at least one panel inorganic layer overlaps the clad part, and comprises a first stop hole penetrating the at least one panel inorganic layer in a thickness direction.

8. The display device of claim 7, further comprising:
a first attachment metal between the substrate and the at least one panel inorganic layer; and
a second attachment metal between the at least one panel inorganic layer and the clad part,
wherein the first attachment metal and the second attachment metal are in direct contact with each other.

9. The display device of claim 8, wherein the second attachment metal is in contact with the first attachment metal in the first stop hole, and in direct contact with the at least one panel inorganic layer.

10. The display device of claim 9, further comprising:
a light-blocking layer between the first transistor and the substrate,
wherein the first attachment metal is disposed on a same layer as the light-blocking layer, and
wherein the second attachment metal is disposed on a same layer as the source electrode or drain electrode of the first transistor.

11. The display device of claim 6, wherein the at least one touch inorganic layer and the third encapsulating layer comprise a second stop hole overlapping the clad part and penetrating the at least one touch inorganic layer and the third encapsulating layer in a thickness direction.

12. The display device of claim 11, further comprising:
a third attachment metal disposed within the second stop hole and in direct contact with the clad part,
wherein the at least one touch inorganic layer comprises a touch buffer layer on the encapsulating part, and a touch insulating layer, and
the touch electrode comprises a first touch electrode on the touch insulating layer and a second touch electrode between the touch buffer layer and the touch insulating layer.

13. The display device of claim 12, wherein the third attachment metal is disposed on a same layer as the first touch electrode.

14. The display device of claim 13, wherein the third attachment metal overlaps the dam.

15. The display device of claim 1, wherein:
the touch part further comprises a first touch organic layer on the touch electrode, and a second touch organic layer on the first touch organic layer; and
the display device further comprises a mold that is in contact with a lateral surface of the substrate, a lateral surface of the first touch organic layer, and a lateral surface of the second touch organic layer.

16. The display device of claim 1, wherein the clad part is in direct contact with the substrate.

17. A display device, comprising:
a substrate comprising a display area including a pixel, and a non-display area disposed adjacent to the display area;
at least one panel inorganic layer on the substrate;
a clad part disposed on the at least one panel inorganic layer in the non-display area and configured to cover an end of the at least one panel inorganic layer;
a dam disposed between the clad part and the display area; and
a touch part disposed on the clad part and the dam, and comprising at least one touch inorganic layer and a touch electrode on the at least one touch inorganic layer,
wherein the at least one touch inorganic layer comprises a stop hole, and the stop hole is disposed between the clad part and the dam.

18. The display device of claim 17, wherein:
the touch part further comprises a first touch organic layer on the touch electrode, and a second touch organic layer on the first touch organic layer; and
the display device further comprises a mold in contact with a lateral surface of the substrate, a lateral surface of the first touch organic layer, and a lateral surface of the second touch organic layer.

19. The display device of claim 18, further comprising:
an encapsulating part between the clad part and the touch part,
wherein the first touch organic layer is in direct contact with the encapsulating part in the stop hole.

20. The display device of claim 17, wherein the clad part is in direct contact with the substrate.
